(19) United States
(12) Patent Application Publication
(10) Pub. No.: US 2014/0352735 A1
(43) Pub. Date: Dec. 4, 2014

(54) ZERO LAG DISPENSE APPARATUS

(71) Applicants: Don C. Burkman, Osceola, WI (US); Cary M. Ley, Andover, MN (US); Kevin T. O'Dougherty, Arden Hills, MN (US); Charlie A. Peterson, Waconia, MN (US)

(72) Inventors: Don C. Burkman, Osceola, WI (US); Cary M. Ley, Andover, MN (US); Kevin T. O'Dougherty, Arden Hills, MN (US); Charlie A. Peterson, Waconia, MN (US)

(73) Assignee: BEIJING SEVENSTAR ELECTRONICS CO. LTD., Beijing (CN)

(21) Appl. No.: 14/288,991

(22) Filed: May 28, 2014

Related U.S. Application Data
(60) Provisional application No. 61/828,406, filed on May 29, 2013.

(51) Int. Cl. H01L 21/67

(52) U.S. Cl. CPC H01L 21/67051
USPC 134/26; 134/95.3

(57) ABSTRACT

A wafer cleaning method includes dispensing liquid chemicals at two flow rates to start a chemical reaction, with the second flow rate being lower than the first. The method also includes dispensing liquid waters at two flow rates to stop a chemical reaction, with the second flow rate being lower than the first.

### BACKGROUND

The present invention relates to dispensing liquid, and, more particularly, to dispensing liquid onto a wafer that covers the wafer substantially quickly and substantially uniformly.

During the fabrication of integrated circuits, a relatively large silicon substrate (also called a wafer) undergoes many individual processing steps to form many individual integrated circuits on its surface. There can be many types of steps used to form these integrated circuits, including cleaning, masking, etching, deposition, diffusion, ion implantation, and polishing, among many others. Oftentimes the cleaning step must be performed between the other steps. The cleaning steps help ensure that the integrated circuits will be free of contamination that could cause harmful defects in the delicate structures of the integrated circuits. Due to the critical requirements of cleanliness for the wafer surfaces, the wafer is kept in clean room conditions and often with automated handling and processing through these many steps. As the technology level of the device structures and processes continue to advance, it is more common for the wafers to be processed on an individual (one by one) basis. This is especially true for the large substrates that are currently 300 mm (11.8 inches) in diameter and also would be true for the next proposed size of 450 mm (17.7 inches). Since the wet chemical processing steps are designed to reduce the contamination level to infinitesimal levels, extreme care must be taken in the design of the system used for processing. The chemicals and gases that come in contact with the wafer are likewise ultra clean and all materials used are designed to minimize any contamination.

While the size of the substrates is increasing, the size of the device structures of the integrated circuits is shrinking. Because the layer thicknesses of the device structures are shrinking, greater process uniformity is required with respect to the fabrication and cleaning of the integrated circuits. More specifically, the wet chemicals that affect the formation of the device structures and the cleaning must be applied uniformly to the wafer. However, given that the liquids are typically dispensed from a single nozzle onto a spinning wafer, some areas of the wafer are covered before others. Because the liquids react with the wafer as soon as they are applied, the areas of the wafer that are wetted first start chemically reacting first. Subsequently, areas of the wafer that are wetted later start chemically reacting later. However, merely rinsing the wafer (and stopping the chemical reaction) in the order that it was initially wetted does not necessarily lead to consistent reaction times across the entire wafer. This heterogeneity of reaction time can lead to undesirable variation in the device structures, which is a symptom of decreased consistency of the fabrication and cleaning of the circuits.

In addition to greater uniformity, the speed at which a wafer is processed is also critical. As with almost any manufacturing process, reducing cycle time increases throughput, which in turn decreases the unit cost of making a device. Therefore, increasing throughput increases profitability of a manufacturing process. It is oftentimes challenging to increase the quality of a process and to shorten the time it takes to perform the process, and doing both at the same time is that much more difficult.

### SUMMARY

According to the present invention, wafer cleaning method includes dispensing liquid chemicals at two flow rates to start a chemical reaction, with the second flow rate being lower than the first. The method also includes dispensing liquid at two flow rates to stop a chemical reaction, with the second flow rate being lower than the first.

In another embodiment, a system for dispensing a liquid onto a wafer includes a chuck and two liquid dispensers. The chuck is for holding the wafer in a wafer holding position and the chuck rotates about a center axis. The liquid dispensers each include a supply tube with an inlet at one end and an outlet at the other end and a valve in between. One of the liquid dispensers dispenses liquid at a substantially higher rate than the other liquid dispenser.

### BRIEF DESCRIPTION OF THE DRAWINGS

FIG. 1 is a perspective view of a wafer cleaning system, including two liquid dispensers dispensing liquid onto a wafer that is held by a chuck.

FIG. 2 is a flow diagram of a method for cleaning a wafer in a process module.

FIG. 3 is a perspective view of an alternate embodiment wafer cleaning system, including an alternate embodiment liquid dispenser dispensing liquid onto a wafer that is held by a chuck.

FIG. 4A is a bottom view of the alternate embodiment liquid dispenser with a dispensing valve in an open position.

FIG. 4B is a bottom view of the alternate embodiment liquid dispenser with the dispensing valve in a closed position.

FIG. 4C is a side partial cross-section view of the alternate embodiment liquid dispenser along line 4C-4C in FIG. 4A.

FIG. 5 is a flow diagram of another alternate embodiment method for cleaning the wafer in the process module.

FIG. 6 is a perspective view of another alternate embodiment wafer cleaning system, including two alternate embodiment liquid dispensers dispensing liquid onto the wafer that is held by the chuck.

FIGS. 7A-7C are bottom views of alternate embodiments of a liquid dispenser having an array of outlets.

FIG. 8 is a top view of the alternate embodiment wafer cleaning system, including two liquid dispensers dispensing liquid onto the wafer.

FIG. 9 is a top view of the alternate embodiment wafer cleaning system, including two liquid dispensers dispensing two liquids onto the wafer.

FIG. 10 is a flow diagram of a method for diluting one liquid on the wafer using another liquid.

### DETAILED DESCRIPTION

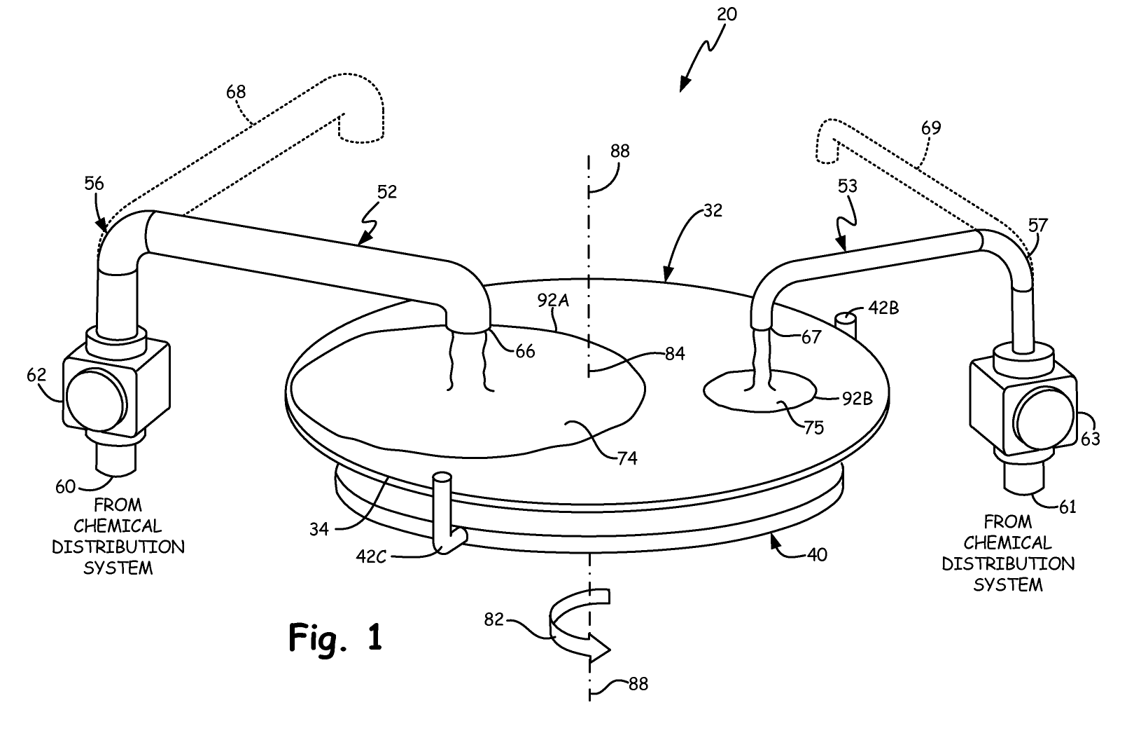

In FIG. 1, a perspective view of wafer cleaning system 20 is shown. FIG. 1 shows wafer 32 (with wafer edge 34), chuck grippers 42B-42C, chuck 40, large liquid dispenser 52, small liquid dispenser 53, supply tube 56, supply tube 57, inlet 60, inlet 61, valve 62, valve 63, outlet 66, outlet 67, resting position 68, resting position 69, large puddle 74, small puddle 75, wafer rotation direction 82, wafer center 84, chuck center axis 88, and liquid menisci 92A-92B.

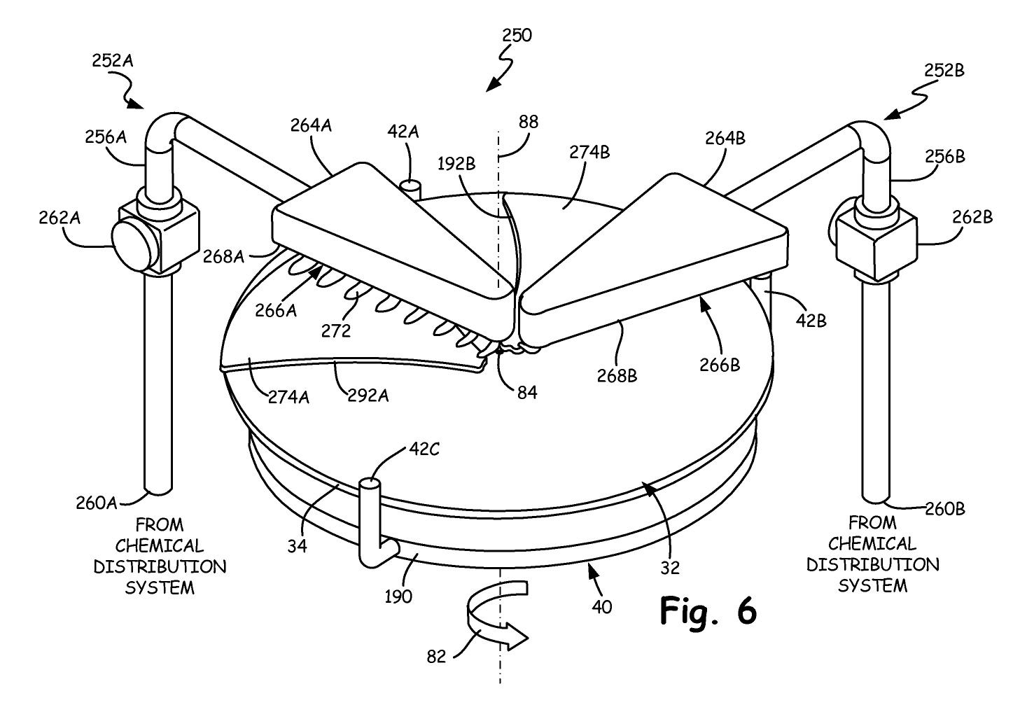

Wafer 32 has wafer edge 34 along the outer perimeter of wafer 32 and wafer center 84 in the center of wafer 32. Wafer 32 is held by chuck 40 using chuck grippers 42A-42C (chuck gripper 42A is shown in FIG. 6). More specifically, chuck 40 has a wafer holding position between chuck grippers 42A-42C, which wafer 32 is occupying in FIG. 1. Chuck 40 rotates wafer 32 in wafer rotation direction 82. Such rotation occurs about chuck center axis 88 of chuck 40, with chuck center axis 88 passing through wafer center 84. In one embodiment, during the dispensing of liquid (as will be discussed below), the rate of rotation of wafer 32 and chuck 40 is approximately sixty revolutions per minute (equivalent to one revolution per second). While the rate of rotation can be different in alternate embodiments, for the sake of simplicity the foregoing rate of rotation will be assumed.

Large dispenser 52 includes supply tube 56, inlet 60, valve 62, and outlet 66. More specifically, inlet 60 is at one end of supply tube 56 and outlet 66 is at the other end. In between inlet 60 and outlet 66 is valve 62. Inlet 60 receives fluid from a chemical distribution system (not shown). Large dispenser 52 can be supplied with any number of pressurized liquids, including ultra pure water (UPW) and cleaning chemicals, such as hydrochloric acid, ammonium hydroxide, hydrogen peroxide, hydrofluoric acid, ammonium fluoride, or any suitable mixture of cleaning chemicals. While the cleaning chemicals react with wafer 32, UPW can stop the reaction therebetween by diluting and/or removing the cleaning chemicals.

Large dispenser 52 is rotatable between a dispensing position (as depicted in FIG. 1) and resting position 68 (shown in phantom). When large dispenser 52 is in the dispensing position, outlet 66 is adjacent to the wafer holding position of chuck 40. In the illustrated embodiment of FIG. 1, outlet 66 is positioned above wafer 32. Because wafer 32 is in the wafer holding position of chuck 40 and the wafer holding position is directly above chuck 40, outlet 66 is also above chuck 40. However, when large dispenser 52 is in resting position 68, then outlet 66 is over neither wafer 32 nor chuck 40. In the illustrated embodiment, outlet 66 and substantially the entire inner diameter of supply tube 56 has an inner diameter of 1.59 centimeters (0.625 inches).

Similarly, small dispenser 53 includes supply tube 57, inlet 61, valve 63, and outlet 67. More specifically, inlet 61 is at one end of supply tube 57 and outlet 67 is at the other end. In between inlet 61 and outlet 67 is valve 63. Inlet 61 receives fluid from a chemical distribution system (not shown). Small dispenser 53 can be supplied with any number of pressurized liquids, including ultra pure water (UPW) and cleaning chemicals, such as hydrochloric acid, ammonium hydroxide, hydrogen peroxide, hydrofluoric acid, ammonium fluoride, or any suitable mixture of cleaning chemicals. In the illustrated embodiment, outlet 67 and substantially the entire inner diameter of supply tube 57 has an inner diameter of 0.635 centimeters (0.250 inches).

Small dispenser 53 is rotatable between a dispensing position (as depicted in FIG. 1) and resting position 69 (shown in phantom). When small dispenser 53 is in the dispensing position, outlet 67 is adjacent to the wafer holding position of chuck 40. In the illustrated embodiment of FIG. 1, outlet 67 is positioned above wafer 32. Because wafer 32 is in the wafer holding position of chuck 40 and the wafer holding position is directly above chuck 40, outlet 67 is also above chuck 40. However, when small dispenser 53 is in resting position 69, then outlet 67 is over neither wafer 32 nor chuck 40.

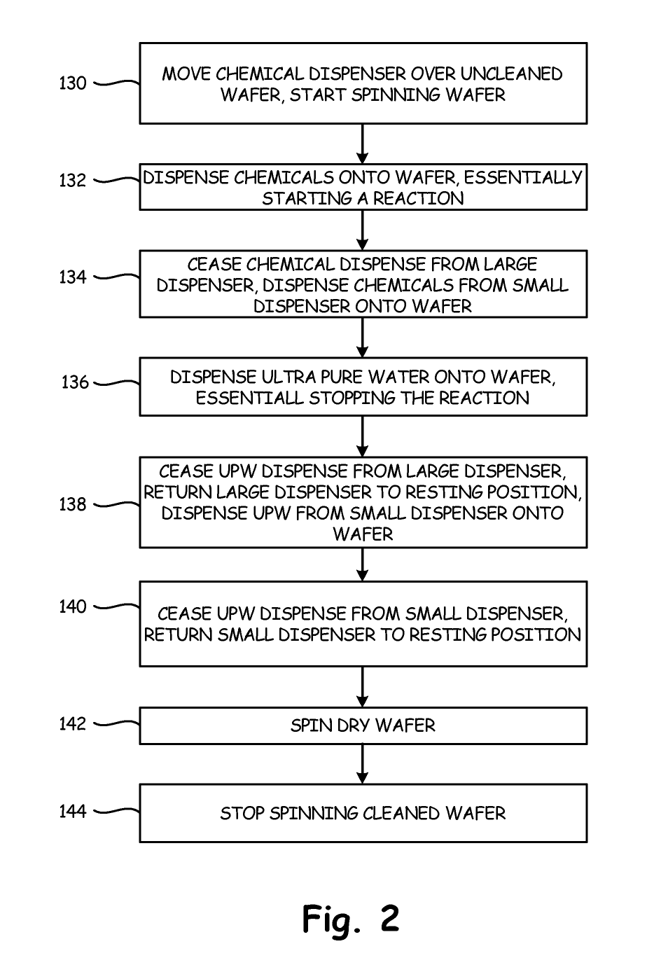

When valve 62 of large dispenser 52 is open, liquid is dispensed out of outlet 66. This action forms large puddle 74 on the top surface of wafer 32. Similarly, when valve 63 of small dispenser 53 is open, liquid is dispensed out of outlet 67. This action forms small puddle 75 on the top surface of wafer 32. Liquid puddles 74, 75 are formed because each puddle 74, 75 has a liquid meniscus 92. A liquid meniscus 92A, 92B is created by the surface tension of the liquid and the interaction between the liquid and the surface upon which it rests. Once a sufficient amount of liquid is dispensed onto wafer 32 (by one or both of dispensers 52, 53), liquid puddles 74, 75 will join and the top of wafer 32 will be covered with liquid. The amount of liquid on top of wafer 32 is the critical meniscus volume, and the exact magnitude of the critical meniscus volume depends on the properties of the liquid, wafer 32, and wafer cleaning system 20. If more than the critical meniscus volume of liquid is dispensed on wafer 32, the excess liquid will flow down over wafer edge 34. The critical meniscus volume of liquid can remain on wafer 32 until, for example, wafer 32 is rotated rapidly (as at step 142 of FIG. 2). In the illustrated embodiment, given that the liquid is ultra pure water, the critical meniscus volume on a wafer 32 that is covered with silicon dioxide at 21 degrees Celsius (70 degrees Fahrenheit) is in the range of 50 to 70 cubic centimeters (3.05-4.27 cubic inches). Henceforth, it will be assumed that the critical meniscus volume for ultra pure water on wafer 32 is 60 cubic centimeters (3.66 cubic inches) for the sake of simplicity of the foregoing dispensing rate calculations.

To ensure that the critical meniscus volume is dispensed rapidly on wafer 32 and is maintained thereafter, liquid is dispensed in two stages. During the first stage, large dispenser 52 (and possibly small dispenser 53, as shown in FIG. 1) dispenses liquid onto wafer 32. During the second stage, only small dispenser 53 dispenses liquid onto wafer 32 to ensure that the entire top surface of wafer 32 remains wet. During at least the second stage, liquid will be running over wafer edge 34, but because small dispenser 53 has a relatively low flow rate, the amount of excess liquid dispensed will be minimized. In the illustrated embodiment, the flow rate of large dispenser 52 is at least enough by itself to cover wafer 32 in four seconds. Preferably, wafer 32 will be covered in 2 seconds, and, more preferably, wafer 32 will be covered in 1 second. Given a wafer 32 diameter of 300 mm, the flow from large dispenser 52 can cover 177 square centimeters per second. Preferably, the flow from large dispenser 52 can cover 353 square centimeters per second, and, more preferably, the flow can cover 707 square centimeters per second. Because the critical meniscus volume is 60 cubic centimeters, the flow rate from large dispenser 52 will be at least 15 cubic centimeters per second. Preferably, the flow rate from large dispenser 52 is at least 30 cubic centimeters per second, and, more preferably, the flow rate is at least 60 cubic centimeters per second. Because outlet 66 of large dispenser 52 (and substantially the entire inner diameter of supply tube 56) is at least 1.59 centimeters (0.625 inches) in diameter, the velocity of the liquid will be less than 30.2 centimeters per second at the more preferable flow rate. At the preferable flow rate, the velocity will be less than 15.1 centimeters per second, and, at the lowest flow rate, the velocity will be less than 7.55 centimeters per second.

After wafer 32 is covered with at least a critical meniscus volume of liquid, the second stage of dispensing commences. This stage only utilizes small dispenser 53, and thereby the flow rate during the second stage is less than the flow rate at the first stage. In the illustrated embodiment, the flow rate during the second stage less than 10 cubic centimeters per second. Because outlet 67 of small dispenser 53 (and substantially the entire inner diameter of supply tube 57) is 0.635 centimeters (0.25 inches) in diameter, the velocity of the liquid will be less than 31.5 centimeters per second.

The components and configuration of liquid dispensers 52 and 53 as shown in FIG. 1 allow for liquid to be dispensed onto wafer 32 to rapidly form and maintain at least a critical meniscus volume of liquid on wafer 32. The high flow rate of large dispenser 52 allows for wafer 32 to be covered with liquid rapidly while rotating wafer 32 at a slow speed. More specifically, wafer 32 can be covered prior to wafer 32 rotating four turns after the commencement of dispensing. Preferably, wafer 32 can be covered prior to wafer 32 rotating two turns, and, more preferably, complete coverage can be achieved after one turn. The second stage allows for contaminants and chemical reaction byproducts to be washed off of wafer 32, over the edge of wafer 34. The second stage also prevents localized drying of the liquid on wafer 32. Because large dispenser 52 has a expansive outlet 66, the velocity of the liquid dispensed is low enough to prevent splashing and waste of the liquid. Also, because small dispenser 53 has a low flow rate, the velocity of the liquid dispensed is low enough to prevent splashing and waste of the liquid.

Depicted in FIG. 1 is one embodiment of the present invention, to which there are alternatives. For example, an additional liquid dispenser can be positioned beneath wafer 32 and dispense liquid onto the bottom side of wafer 32. For another example, only large dispenser 52 can be utilized during the first stage of dispensing.

In FIG. 2, a flow diagram of a method for cleaning uncleaned wafer 32 in wafer cleaning system 20 is shown. Shown in FIG. 2 are steps 130, 132, 134, 136, 138, 140, 142, and 144.

At step 130, large dispenser 52 and small dispenser 53 are raised up from resting positions 68, 69, respectively; rotated over uncleaned wafer 32; and dropped down slightly near the surface of uncleaned wafer 32. Also at step 130, a wafer spin motor (not shown) connected to chuck 40 (shown in FIG. 1) begins rotating uncleaned wafer 32. At step 132, at least large dispenser 52 (and possibly also small dispenser 53) dispenses chemicals onto uncleaned wafer 32 while uncleaned wafer 32 is spinning. At step 134, large dispenser 52 ceases dispensing and small dispenser 53 dispenses chemicals onto wafer 32. At step 136, at least large dispenser 52 (and possibly also small dispenser 53) dispenses ultra pure water (UPW) onto spinning wafer 32. At step 138, large dispenser 52 ceases dispensing and returns to resting position 68, while small dispenser 53 dispenses UPW onto spinning wafer 32. At step 140, small dispenser 53 ceases dispensing UPW and returns to resting position 69. At step 142, the rate of rotation of wafer 32 is adjusted to spin dry newly cleaned wafer 32. In the present embodiment, the rotational rate is substantially increased at step 142. At step 144, rotation of cleaned wafer 32 ceases.

The process of cleaning uncleaned wafer 32 as discussed in FIG. 2 allows for wafer 32 to be cleaned by covering wafer 32 with chemicals that are rinsed off with UPW. Because of the two stage dispensing of chemicals (at steps 132, 134) and of UPW (at steps 136, 138), the chemical reaction between the liquid chemicals and wafer 32 is started across the entire wafer 32 within four seconds and later stopped across the entire wafer 32 within four seconds. Preferably, the reaction is started and later stopped within two seconds each, and, more preferably, the reaction is started and later stopped within one second each.

Depicted in FIG. 2 is one embodiment of the present invention, to which there are alternatives. For example, small dispenser 53 can be moved from resting position 69 at step 132. For another example, as previously stated, wafer cleaning system 20 can perform an etching operation on wafer 32. In such an embodiment, at least large dispenser 52 dispenses etching chemical that essentially starts a chemical reaction with wafer 32 at step 132. Then, at step 138, at least large dispenser 52 dispenses UPW that dilutes and/or rinses the etching chemical off of wafer 32, essentially stopping the chemical reaction with wafer 32.

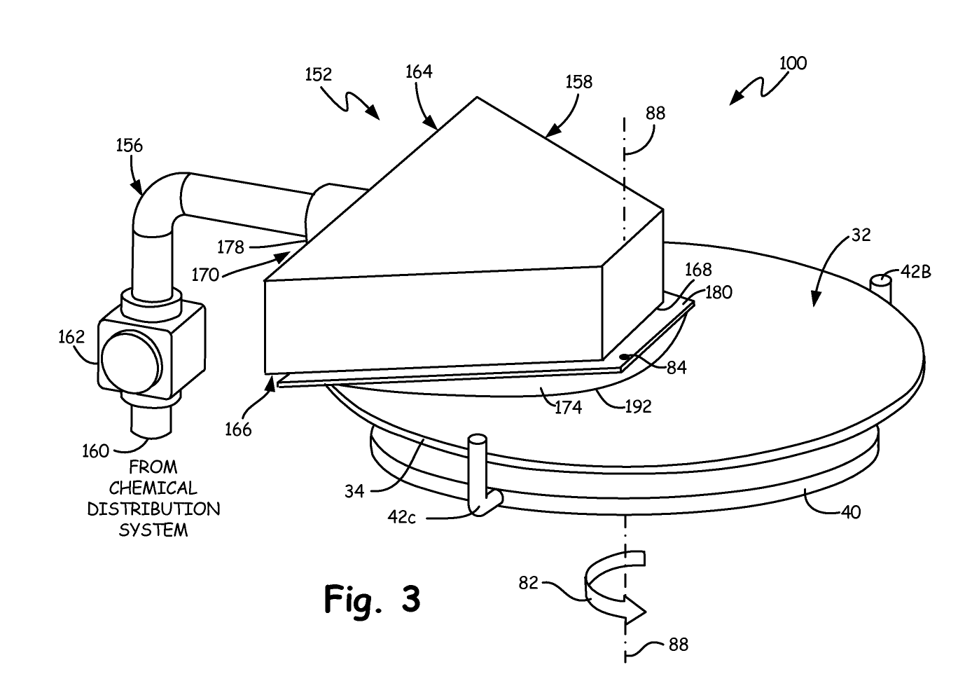

In FIG. 3, a perspective view of an alternate embodiment wafer cleaning system 100 is shown, including an alternate embodiment liquid dispenser 152 dispensing liquid onto wafer 32 that is held by chuck 40. Shown in FIG. 3 are wafer 32, chuck grippers 42B-42C, chuck 40, small dispenser 53, supply tube 57, inlet 61, valve 63, outlet 67, resting position 69, small puddle 75, liquid meniscus 92B, liquid dispenser 152, supply tube 156, liquid reservoir 158, supply tube inlet 160, flow control valve 162, reservoir fill side 164, reservoir dispense side 166, dispensing plate 168, dispensing valve 170, liquid puddle 174, valve actuator 178, valve plate 180, wafer rotation direction 82, wafer center 84, wafer edge 34, chuck center axis 88, and liquid meniscus 192.

In wafer cleaning system 100, there are two liquid dispensers 53, 152. For the present intents and purposes, the configuration and function of liquid dispenser 53 is substantially the same as liquid dispenser 53 of wafer cleaning system 20 (shown in FIG. 1). On the other hand, liquid dispenser 152 is an alternate embodiment liquid dispenser from liquid dispenser 52 of wafer cleaning system 20.

Liquid dispenser 152 includes supply tube 156 and liquid reservoir 158. At one end of supply tube 156 is supply tube inlet 160. The other end of supply tube 156 is attached to reservoir fill side 164 of liquid reservoir 158, and liquid reservoir 158 is fluidly connected to supply tube 156. Situated in supply tube 156 is flow control valve 162. As stated previously, liquid reservoir 158 has reservoir fill side 164 as one side of liquid reservoir 158. In the illustrated embodiment, reservoir fill side 164 is on the outward side of liquid reservoir 158 because reservoir fill side 164 is on the opposite side of liquid reservoir 158 from wafer center 84. Liquid reservoir 158 also has reservoir dispensing side 166, which faces wafer 32. Liquid reservoir 158 has dispensing plate 168 which is on reservoir dispense side 166. Dispensing valve 170 comprises valve plate 180 and valve actuator 178. Valve plate 180 is slidably positioned under dispensing plate 168 and is connected to valve actuator 178. Valve actuator 178 is attached to liquid reservoir 158 on reservoir fill side 164.

When liquid dispenser 152 is in the dispensing position (as at step 132 or step 136 in FIG. 2), reservoir dispense side 166 of liquid reservoir 158 is adjacent to the wafer holding position of chuck 40. In FIG. 3, reservoir dispense side 166 of liquid reservoir 158 is positioned above wafer 32, and liquid dispenser 152 is in the dispensing position. Because wafer 32 is in the wafer holding position of chuck 40 and the wafer holding position is directly above chuck 40, liquid reservoir 158 is also above chuck 40. However, when liquid dispenser 152 is in the resting position (similar to resting position 68 in FIG. 1), then liquid dispenser 152 is over neither wafer 32 nor chuck 40.

Liquid dispenser 152 receives pressurized liquid from a liquid source, such as chemical distribution system (not shown). The pressurized liquid enters liquid dispenser 152 through supply tube inlet 160. When flow control valve 162 is open, the liquid travels through supply tube 156 and into liquid reservoir 158. Once full, liquid reservoir 158 is pressurized by the liquid, and liquid reservoir 158 retains the liquid until it is time to dispense the liquid (such as at step 132 or step 136 in FIG. 2).

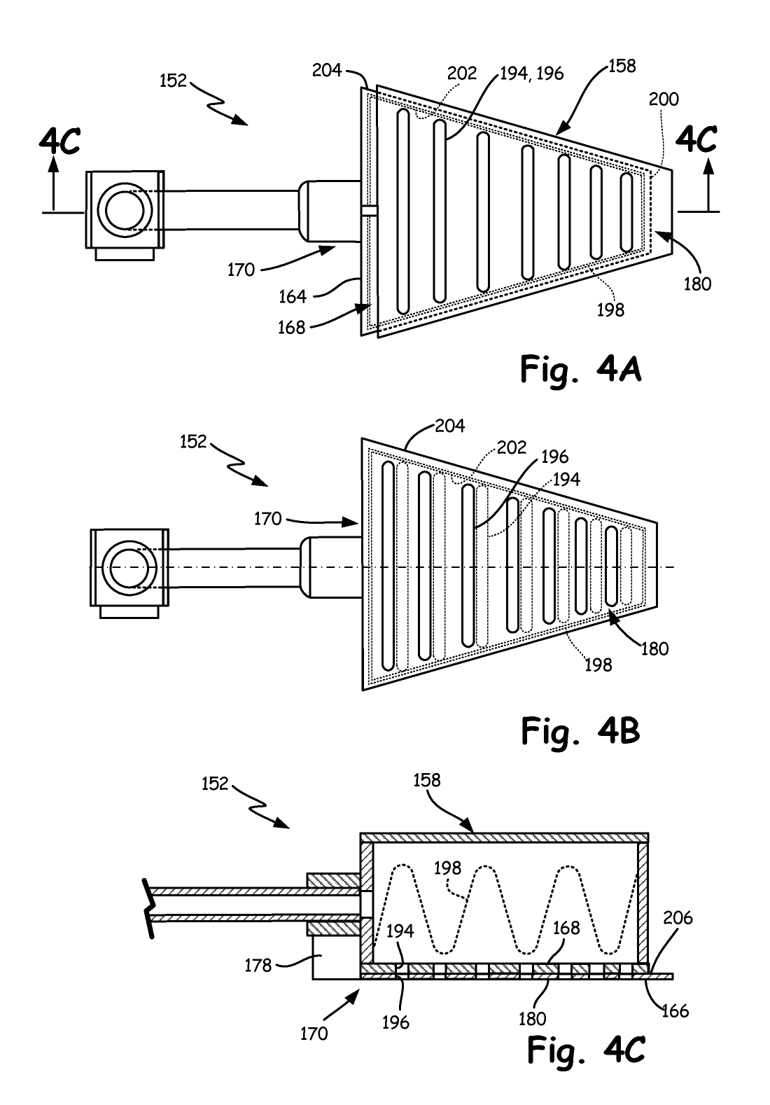

When dispensing valve 170 is open, the liquid is dispensed out of liquid reservoir 158. In the illustrated embodiment, the liquid is dispensed onto wafer 32 though a plurality of liquid streams (as described later with FIGS. 4A-4C), forming liquid puddle 174 on wafer 32. The liquid is dispensed in two stages. During the first stage, substantially all of the liquid in liquid reservoir 158 is emptied onto wafer 32. The amount dispensed in this first stage is at least the critical meniscus volume. The flow rate during the first stage is greater than that during the second stage. In the illustrated embodiment of a wafer 32 diameter of 300 mm, the flow rate during the first stage can cover 177 square centimeters per second. Preferably, the flow rate can cover 353 square centimeters per second, and, more preferably, the flow rate can cover 707 square centimeters per second. Because the critical meniscus volume is 60 cubic centimeters, the flow rate from liquid reservoir 158 will be at least 15 cubic centimeters per second. Preferably, the flow rate is at least 30 cubic centimeters per second, and, more preferably, the flow rate is at least 60 cubic centimeters per second.

Once liquid reservoir 158 is substantially emptied, the second stage commences. In the second stage, liquid is flowed out of liquid reservoir 158 at the same rate that liquid is supplied to liquid reservoir 158 through supply tube 156. The flow rate during the second stage is less than the flow rate at the first stage. In the illustrated embodiment, the flow rate during the second stage less than 20 cubic centimeters per second (1.2 cubic inches per second). Preferably, the flow rate during the second stage is less than 10 cubic centimeters per second (0.61 cubic inches per second).

As an alternative or a supplement to the second stage liquid being flowed through liquid reservoir 158, liquid is flowed out of small dispenser 53 during the second stage. Although in such an embodiment, the flow rate during the second stage is still less than the flow rate at the first stage. If only small dispenser 53 is dispensing during the second stage, then, the flow rate through small dispenser 53 is less than 20 cubic centimeters per second (1.2 cubic inches per second). Preferably, the flow rate through small dispenser 53 is less than 10 cubic centimeters per second (0.61 cubic inches per second). Alternatively, if both dispensers 53, 152 are dispensing during the second stage, then the combined flow rate during the second stage is still less than the flow rate at the first stage. In such an embodiment, the combined flow rate during the second stage less than 20 cubic centimeters per second (1.2 cubic inches per second). Preferably, the combined flow rate during the second stage is less than 10 cubic centimeters per second (0.61 cubic inches per second).

As stated previously, after the liquid is dispensed onto wafer 32, it forms liquid puddle 174 on the top of wafer 32. If more than the critical meniscus volume of liquid is dispensed on wafer 32, and the liquid will flow down over wafer edge 34. Such a situation may occur during the first stage of dispensing and will occur during the second stage of dispensing.

In the illustrated embodiment, the amount of liquid dispensed during the first stage of dispensing is at least the critical meniscus volume. Preferably, the amount of liquid dispensed during the first stage is one third more than the critical meniscus volume in order to ensure that the critical meniscus volume of liquid is deposited onto wafer 32. More preferably, the amount of liquid dispensed during the first stage is two thirds more than the critical meniscus volume in order to ensure that the critical meniscus volume of liquid is deposited onto wafer 32.

In the illustrated embodiment, given the flow rate during the first stage of dispensing and the critical meniscus volume, wafer 32 can be covered in less than three seconds with ultra pure water at 21 degrees Celsius (70 degrees Fahrenheit). Preferably, wafer 32 can be covered in less than two seconds, and, more preferably, wafer 32 can be covered in less than one second.

When dispensing valve 170 is closed, liquid is no longer dispensed out of liquid reservoir 158. Due to the liquid flowing out of liquid reservoir 158 when dispensing valve 170 was open, more liquid will need to be added to liquid reservoir. The process for filling liquid reservoir 158 can occur when liquid dispenser 152 is in the dispensing position, in the resting position, or when traveling between these two positions.

The components and configuration of liquid dispenser 152 as shown in FIG. 3 allow for liquid to be dispensed onto wafer 32 in two stages to form liquid puddle 174. The high flow rate and ample volume of the first stage allows for wafer 32 to be covered with liquid rapidly while rotating wafer 32 at a slow speed. Thereby liquid puddle 174 can cover the entire top of wafer 32 without being disrupted by liquid being flung off of wafer 32 by the rapid rotation thereof. More specifically, wafer 32 can be covered prior to wafer 32 rotating two turns after the commencement of dispensing. Preferably, wafer 32 can be covered prior to wafer 32 rotating a single turn after the commencement of dispensing. The second stage allows for contaminants and chemical reaction byproducts to be washed off of wafer 32, over the edge of wafer 32. The second stage also prevents localized drying of the liquid on wafer 32, which avoids locally stopping the reaction between the wafer and the liquid.

Depicted in FIG. 3 is one embodiment of the present invention, to which there are alternatives. For example, liquid dispenser 152 can be positioned beneath wafer 32 and dispense liquid onto the bottom side of wafer 32. For another example, liquid can flow into liquid reservoir 158 during the first stage of dispensing and continue through to the second stage of dispensing.

In FIG. 4A, a bottom view of alternate embodiment liquid dispenser 152 is shown with dispensing valve 170 in an open position. In FIG. 4B, a bottom view of liquid dispenser 152 is shown with dispensing valve 170 in a closed position. In FIG. 4C, a side cross-section view of the liquid dispenser 152 along line 4C-4C in FIG. 4A is shown. Shown in FIGS. 4A-4C are liquid dispenser 152, liquid reservoir 158, reservoir fill side 164, reservoir dispense side 166, dispensing plate 168, dispensing valve 170, valve actuator 178, valve plate 180, reservoir outlets 194, dispensing valve outlets 196, heating element 198, tip 200, side wall interior 202, side wall exterior 204, and gasket 206.

The parts and connections of liquid dispenser 152 are as described with FIG. 3, with some additional features shown in FIGS. 4A-4C. For example, liquid dispenser 152 can dispense liquid over a trapezoidal area. In the illustrated embodiment this trapezoidal area is similar to a circular sector, wherein a circular sector is a wedge or pie shape. The pattern of dispensing can occur because of two substantially identical arrays of outlets on reservoir dispense side 166. The first is an array of reservoir outlets 194, which are slots in dispensing plate 168 of liquid reservoir 158. The second is an array of dispensing valve outlets 196, which are slots in valve plate 180. When dispensing valve 170 is in the open position (as shown in FIG. 4A), reservoir outlets 194 line up with the dispensing valve outlets 196. Thereby, liquid can flow out of liquid reservoir 158 in a plurality of liquid streams, with each liquid stream originating from a pair of a reservoir outlet 194 and a dispensing valve outlet 196.

In the illustrated embodiment, the size of outlets 194 and 196 near reservoir fill side 164 of liquid dispenser 152 is greater than the size of outlets 194 and 196 near tip 200 of liquid dispenser 152. More generally, the configuration of outlets 194 and 196 creates an increasing gradient of dispensing area from tip 200 to reservoir fill side 164 of liquid dispenser 152. This gradient exists because the circumference of wafer 32 (as shown in FIG. 3) increases the farther away from wafer center 84 the circumference is measured. This means that there is more area to cover on wafer 32 near wafer edge 34 than near wafer center 84. Thereby, the increasing size of outlets 194 and 196 from tip 200 to reservoir fill side 164 compensates for the increasing circumferential area from wafer center 84 to wafer edge 34, and the top of wafer 32 (as shown in FIG. 3) can be coated evenly with liquid.

As shown in FIG. 4B, valve plate 180 slides to close dispensing valve 170. Valve plate 180 is slid by valve actuator 178, and in the illustrated embodiment, when valve plate 180 is slid rearward by valve actuator 178, dispensing valve 170 is in the closed position. From the closed position, liquid dispenser 152 cannot dispense liquid. This is because reservoir outlets 194 and dispensing valve outlets 196 are no longer aligned. Therefore, the solid portion of valve plate 180 is covering reservoir outlets 194, and the solid portion of dispensing plate 168 is covering dispensing valve outlets 196. This arrangement of dispensing plate 168 and valve plate 180 prevents liquid from flowing out of liquid reservoir 158.

In the illustrated embodiment, the distance between each reservoir outlet 194 and its corresponding dispensing valve outlet 196 is substantially the same for each pair of outlets 194 and 196 when dispensing valve 170 is closed. This means that when valve plate 180 is slid to the open position by valve actuator 178, dispensing commences from each pair of outlets 194 and 196 substantially simultaneously. Similarly, when valve plate 180 is slid to the closed position, dispensing ceases substantially simultaneously from each pair of outlets 194 and 196.

As stated previously and currently shown in FIG. 4C, when valve plate 180 is forward, the array of reservoir outlets 194 lines up with the array of dispensing valve outlets 196. This allows liquid inside of liquid reservoir to be dispensed out of liquid dispenser 152. In addition, gasket 206 is sandwiched between dispensing plate 168 and valve plate 180. Gasket 206 prevents the pressurized liquid inside of liquid reservoir 158 from leaking past valve plate 180 when dispensing valve 170 is in the closed position. More specifically, gasket 206 allows valve plate 180 to seal reservoir outlets 194 when valve actuator 178 has moved valve plate 180 sufficiently rearward.

Also shown in FIG. 4C is heating element 198. Heating element 198 is an electrical resistance heater that uses electrical energy to produce heat. In the illustrated embodiment, heating element 198 is situated in the side walls of liquid reservoir 158, between side wall interior 202 and side wall exterior 204 and is wound in an oscillating manner. This allows heating element 198 to heat the liquid in liquid reservoir 158 regardless of the level of the liquid. Heating element 198 is used to control the temperature of the liquid inside liquid reservoir 158 as part of a closed loop system.

The components and configuration of liquid dispenser 152 as shown in FIGS. 4A-4C allow for the temperature of the liquid to be maintained at a substantially constant and known temperature, regardless of the incoming temperature of the liquid prior to entering liquid reservoir 158. In addition, the configuration of dispensing plate 168 and valve plate 180 allow for dispensing that compensates for the changing characteristics of circumference and area of wafer 32 (as shown in FIG. 3) the farther away from wafer center 84 the dispensing occurs. More specifically, the arrays of reservoir outlets 194 and dispensing valve outlets 196 have more flow area available the farther away from tip 200 than near tip 200.

Depicted in FIGS. 4A-4C is one embodiment of the present invention, to which there are alternatives. For example, the gradient of increasing of flow area through dispensing plate 168 and valve plate 180 from tip 200 to reservoir fill side 164 can be achieved using an array of reservoir outlets 194 and an array of dispensing valve outlets 196 that each has more numerous outlets 194 and 196 farther from tip 200. For another example, valve plate 180 can be slid forward or sideways to close dispensing valve 170. Although in the latter embodiment, outlets 194 and 196 are oriented orthogonally to those shown in FIGS. 4A-4C. For a further example, heating element 198 can be a fluid pathway for circulating hot or cold fluid within the side walls of liquid reservoir 158 in order to control the temperature of the liquid. For yet another example, gasket 206 can be a porous membrane that liquid can flow through, such as a sheet of polytetrafluoroethylene (PTFE) that extends over the entire surface of dispensing plate 168.

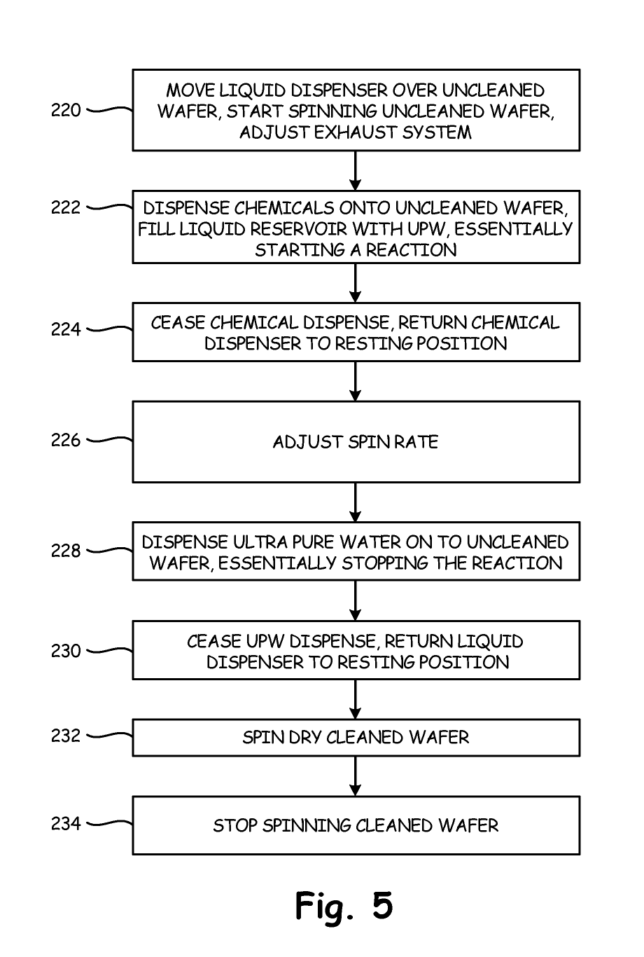

In FIG. 5, a flow diagram of an alternate embodiment method for cleaning wafer 32 in wafer cleaning system 100 is shown. Shown in FIG. 5 are steps 220, 222, 224, 226, 228, 230, 232, and 234. In this alternate embodiment, small dispenser 53 and liquid dispenser 152 are both used to dispense chemicals and ultra pure water (UPW) onto uncleaned wafer 32. Therefore, dispensers 53, 152 receive both chemicals and UPW from the chemical distribution system (not shown).

At step 220, dispensers 53, 152 are raised up from their respective resting positions, rotated over uncleaned wafer 32, and dropped down slightly near the surface of uncleaned wafer 32. Also at step 220, a wafer spin motor (not shown) connected to chuck 40 (shown in FIG. 3) begins rotating uncleaned wafer 32. At step 222, liquid dispenser 152 dispenses chemicals out of liquid reservoir 158 onto uncleaned wafer 32 while uncleaned wafer 32 is spinning. This essentially starts the reaction between the chemicals and wafer 32. At step 224, chemicals are dispensed from both dispensers 53, 152. At step 226, liquid dispenser 152 ceases dispensing by closing dispensing valve 170, and liquid reservoir 158 is filled with ultra pure water (UPW). Also at step 226, small dispenser 53 continues to dispense chemicals. At step 228, small dispenser 53 ceases dispensing chemicals and switches to dispensing UPW. Also at step 228, liquid dispenser 152 dispenses UPW from liquid reservoir 158 onto wafer 32 while wafer 32 is spinning. This essentially stops the reaction between the chemicals and wafer 32. At step 230, dispensers 53,152 cease dispensing and are moved back to their respective resting positions. At step 232, the rate of rotation of the wafer spin motor (not shown) is adjusted to spin dry wafer 32. In the present embodiment, the rotational rate is substantially increased at step 232. At step 234, the wafer spin motor ceases rotation of cleaned wafer 32.

The process of cleaning uncleaned wafer 32 as discussed in FIG. 5 allows for wafer 32 to be cleaned. More specifically, the cleaning process is accomplished using a single liquid dispenser 152. Because of the volume of chemicals dispensed at step 222 and of UPW at step 228, the chemical reaction between the liquid chemicals and wafer 32 is started across the entire wafer 32 within four seconds and later stopped across the entire wafer 32 within four seconds. Preferably, the reaction is started and later stopped within two seconds each, and, more preferably, the reaction is started and later stopped within one second each.

Depicted in FIG. 5 is one embodiment of the present invention, to which there are alternatives. For example, as previously stated, wafer cleaning system 100 can perform an etching operation on wafer 32. In such an embodiment, liquid dispenser 152 dispenses etching chemical that chemically reacts with wafer 32 at step 222. Then, at step 228, dispensers 53, 152 dispense UPW that dilutes and/or rinses the etching chemical off of wafer 32, slowing or stopping the chemical reaction with wafer 32. For another example, dispensers 53, 152 can dispense another cleaning chemical at step 228 instead of UPW. In such an embodiment, liquid reservoir 158 is filled with that cleaning chemical at step 226. For a further example, both dispensers 53, 152 may not simultaneously dispense chemicals. In such an embodiment, step 224 is unnecessary. For yet another example, small dispenser 53 may not dispense UPW. In such an embodiment, all of the UPW used in step 228 would come from liquid dispenser 152. For yet another example, small dispenser 53 can commence dispensing chemicals at step 222. For yet another example, small dispenser 53 may commence dispensing UPW after liquid reservoir 158 is emptied at step 228.

In FIG. 6, a perspective view of an alternate embodiment wafer cleaning system 250 is shown, including alternate embodiment liquid dispensers 252A-252B dispensing liquid onto wafer 32 that is held by chuck 40. Shown in FIG. 6 are wafer 32, chuck grippers 42A-42C, chuck 40, wafer rotation direction 82, wafer center 84, wafer edge 34, chuck center axis 88, chuck edge 190, liquid dispensers 252A-252B, supply tubes 256A-256B, liquid reservoirs 258A-258B, supply tube inlets 260A-260B, flow control valves 262A-262B, reservoir fill sides 264A-264B, reservoir dispense sides 266A-266B, dispensing plates 268A-268B, liquid streams 272, liquid puddles 274A-274B, and liquid menisci 292A-292B. Although liquid dispenser 252A and liquid dispenser 252B may not be identical, it should be noted that for the present purposes, liquid dispenser 252A is representative of liquid dispensers 252A-252B in at least the configuration and operation thereof. However, the relative locations of liquid dispensers 252A-252B with respect to chuck 40 are different and will be discussed accordingly.

As stated previously, wafer 32 has wafer edge 34 along the outer perimeter of wafer 32 and wafer center 84 in the center of wafer 32. Wafer 32 is held by chuck 40 using chuck grippers 42A-42C. More specifically, chuck 40 has a wafer holding position between 42A-42C, which wafer 32 is occupying in FIG. 6. Chuck 40 rotates wafer 32 in wafer rotation direction 82. Such rotation occurs about chuck center axis 88 of chuck 40, with chuck center axis 88 passing through wafer center 84.

Liquid dispenser 252A includes supply tube 256A and liquid reservoir 258A. At one end of supply tube 256A is supply tube inlet 260A. The other end of supply tube 256A is attached to reservoir fill side 264A of liquid reservoir 258A, and liquid reservoir 258A is fluidly connected to supply tube 256A. Situated in supply tube 256A is flow control valve 262A. Liquid reservoir 258A has reservoir fill side 264A as one side of liquid reservoir 258A. In the illustrated embodiment, reservoir fill side 264A is on the outward side of liquid reservoir 258A because reservoir fill side 264A is on the opposite side of liquid reservoir 258A from wafer center 84. Liquid reservoir 258A also has head dispensing side 266A as another side of liquid reservoir 258A. Liquid reservoir 258A has dispensing plate 268A which is on reservoir dispense side 266A.

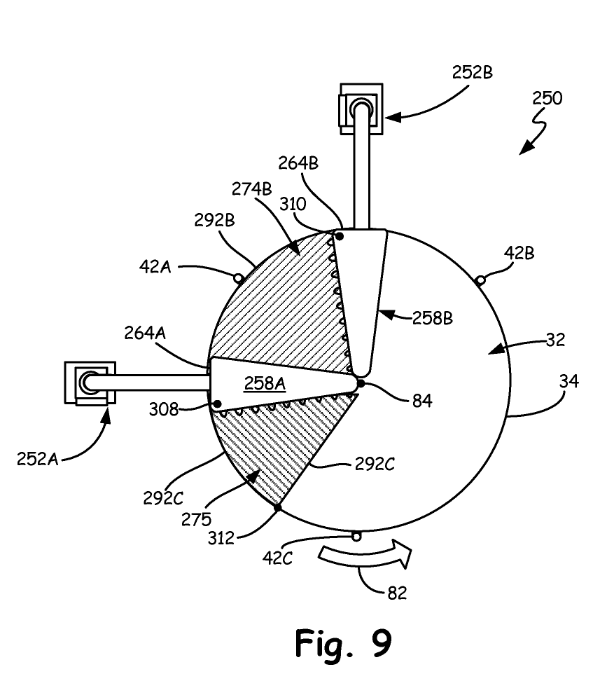

When liquid dispenser 252A is in the dispensing position (as at step 132 or step 136 in FIG. 2), reservoir dispense side 266A of liquid reservoir 258A is adjacent to the wafer holding position of chuck 40. In FIG. 9, reservoir dispense side 266A of liquid reservoir 258A is positioned above wafer 32, and liquid dispenser 252A is in the dispensing position. Liquid reservoir 258A extends from near wafer center 84 radially outward towards wafer edge 34 along a central radial line. More specifically, the edges of liquid reservoir 258A extend from near wafer center 84 radially outward towards wafer edge 34 along two radial lines. Thereby, liquid reservoir 258A is over a circular sector of wafer 32. Because wafer 32 is in the wafer holding position of chuck 40 and the wafer holding position is above chuck 40, liquid reservoir 258A is above chuck 40. Also, liquid reservoir 258A extends from near chuck center axis 88 radially outward towards chuck edge 190 along a central radial line. More specifically, the edges of liquid reservoir 258A extend from near chuck center axis 88 radially outward towards chuck edge 190 along two radial lines. Thereby, liquid reservoir 258A is also above a circular sector of chuck 40. However, when liquid dispenser 252A is in the resting position (similar to resting position 68 in FIG. 1), then liquid dispenser 252A is above neither wafer 32 nor chuck 40.

Liquid dispenser 252A receives pressurized liquid from a liquid source, such as the chemical distribution system (not shown). The pressurized liquid enters liquid dispenser 252A through supply tube inlet 260A. When flow control valve 262A is open, the liquid travels through supply tube 256A, into liquid reservoir 258A, and onto wafer 32. When flow control valve 262A is closed, liquid flow through supply tube 260A stops and dispensing from liquid reservoir 258A ceases.

For the current purposes, it is beneficial to discuss liquid dispensers 252A-252B separately. Each liquid dispenser 252A-252B has a pressurized liquid source, such as chemical distribution system (not shown). The chemical distribution system can distribute the same liquid or different liquids to both liquid dispensers 252A-252B.

Moreover, liquid dispensers 252A-252B are positioned next to chuck 40, with liquid dispenser 252B being positioned circumferentially around chuck 40 from liquid dispenser 252A. Therefore, while liquid dispenser 252A dispenses along a first central radial line of wafer 32 and chuck 40, liquid dispenser 252B dispenses along a second central radial of wafer 32 and chuck 40. These two radii are circumferentially spaced apart by an angle. More specifically, while liquid dispenser 252A dispenses over a first circular sector of wafer 32 and chuck 40, liquid dispenser 252B dispenses over a second circular sector of wafer 32 and chuck 40. These two sectors are circumferentially spaced apart by an angle. In the illustrated embodiment, the angle is ninety degrees center-to-center.

In the illustrated embodiment, after the liquid is dispensed onto wafer 32 from liquid dispenser 252A, it forms liquid puddle 274A on the top of wafer 32. After the liquid is dispensed onto wafer 32 from liquid dispenser 252B, it forms liquid puddle 274B on the top of wafer 32. In addition, once wafer 32 has been rotated such that liquid dispenser 252A is dispensing sufficiently near the area that liquid dispenser 252B has previously dispensed onto, liquid menisci 292A-292B will be broken there and liquid puddles 274A-274B will join. This creates single mixed puddle 275 (as shown later with FIG. 9). Mixed puddle 275 can remain on wafer 32 until, for example, wafer 32 is rotated rapidly (as at step 142 of FIG. 2).

The components and configuration of liquid dispensers 252A-252B as shown in FIG. 6 allow for liquid to be dispensed onto wafer 32 and form liquid puddles 274A-274B and/or mixed puddle 275. More particularly, liquid can be dispensed onto wafer 32 along two central radial lines and in two circular sectors that are circumferentially spaced apart. This allows for wafer 32 to be covered with liquid rapidly, while only rotating wafer 32 at a slow speed. Thereby, liquid puddles 274A-274B can be formed by liquid menisci 292A-292B without being disrupted by liquid being flung off of wafer 32 by the rapid rotation thereof.

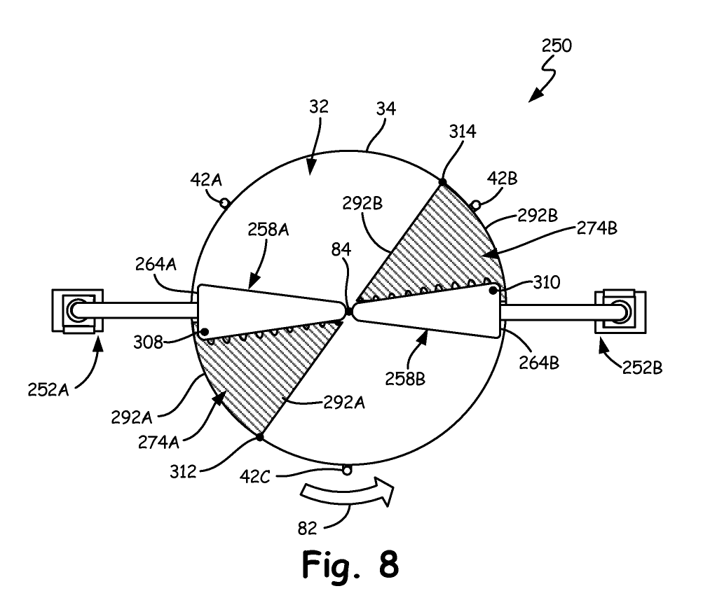

Depicted in FIG. 6 is one embodiment of the present invention, to which there are alternatives. For example, at least one of liquid dispensers 252A-252B can be positioned beneath wafer 32 and dispense liquid onto the underneath side of wafer 32. For another example, liquid dispensers 252A-252B can be positioned in different positions other than ninety degrees away from each other (for example, one hundred eighty degrees, as shown in FIG. 8). For a further example, either one of liquid dispensers 252A-252B can receive the same liquid from the chemical distribution system (not shown) or each liquid dispenser 252A-252B can receive two different liquids from the chemical distribution system (not shown but as discussed previously with FIG. 5). For yet another example, liquid dispensers 252A-252B can be trapezoidally shaped like liquid dispenser 152 (as shown in FIG. 3).

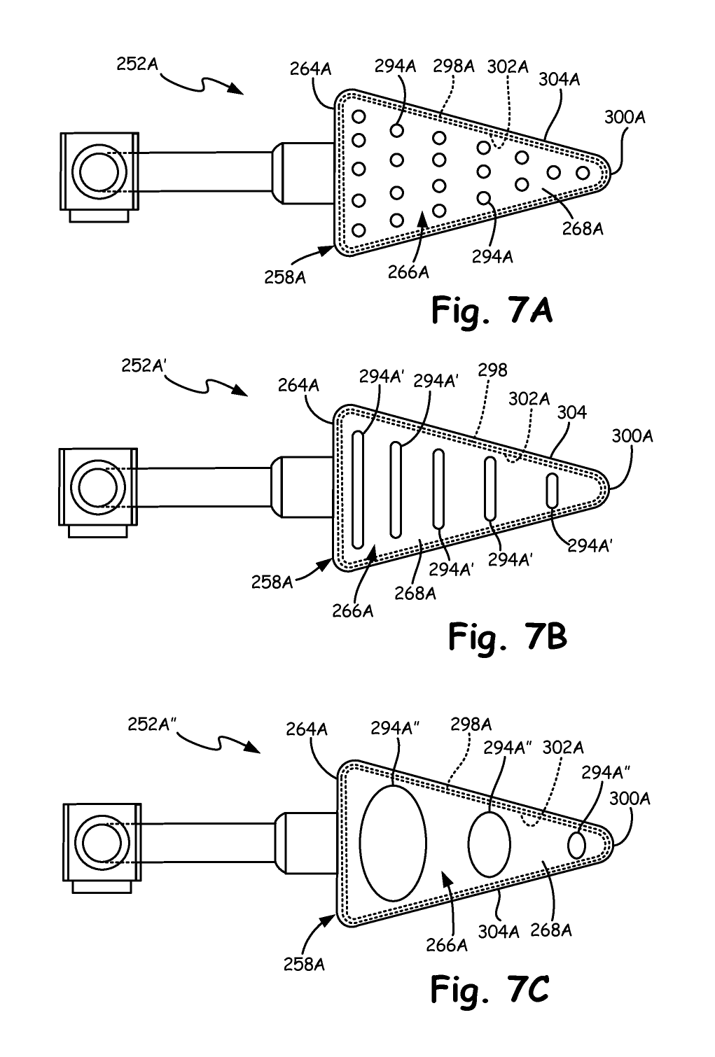

In FIG. 7A, a bottom view of alternate embodiment liquid dispenser 252A is shown having an array of circular head outlets 294A of equal size. In FIG. 7B, a bottom view of alternate embodiment liquid dispenser 252A′ is shown having an array of slot-shaped head outlets 294A′ of different lengths. In FIG. 7C, a bottom view of alternate embodiment liquid dispenser 252A″ is shown having an array of elliptical head outlets 294A″ of different sizes. Shown in FIGS. 7A-7C are liquid dispensers 252A/252A′/252A″, liquid reservoir 258A, reservoir fill side 264A, reservoir dispense side 266A, dispensing plate 268A, head outlets 294A/294A′/294A″, heating element 298A, tip 300A, side wall interior 302A, and side wall exterior 304A. As stated previously, although liquid dispensers 252A-252B may not be identical, for the present purposes, liquid dispensers 252A/252A′/252A″ represent liquid dispensers 252A-252B.

The parts and connections of liquid dispenser 252A are as described with FIG. 6, with some additional features shown in FIGS. 7A-7C. For example, each alternate embodiment liquid dispenser 252A/252A′/252A″ shown in FIGS. 7A-7C has heating element 298A. Heating element 298A is situated in the side walls of liquid reservoir 258A, between side wall interior 302A and side wall exterior 304A. In the illustrated embodiment, heating element 298A is an electrical resistance heater that uses electrical energy to produce heat. Heating element 298A is used to control the temperature of the liquid inside liquid reservoir 258A as part of a closed loop system.

Shown in FIG. 7A is that liquid dispenser 252A can dispense along a line from tip 300A to reservoir fill side 264A. More specifically, liquid dispenser 252A can dispense over a shape that is similar to a circular sector, in the illustrated embodiment. This can occur because of an array of head outlets 294A, which are holes in dispensing plate 268A of liquid reservoir 258A. When flow control valve 262A is in the open position, liquid can flow out of liquid reservoir 258A in a plurality of liquid streams 272 (as shown in FIG. 6). Each liquid stream 272 originates from a head outlet 294A in the array of head outlets 294A.

In FIG. 7A, there are more head outlets 294A near reservoir fill side 264A of liquid dispenser 252A than near tip 300A of liquid dispenser 252A. More generally, the configuration of the array of head outlets 294A creates an increasing gradient of available dispensing area from tip 300A to reservoir fill side 264A of liquid dispenser 252A. This gradient exists because the circumference of wafer 32 (as shown in FIG. 6) increases the farther away from wafer center 84 the circumference is measured. This means that there is more area to cover on wafer 32 near wafer edge 34 than near wafer center 84. Thereby, the increasing number of outlets 294A from tip 300A to reservoir fill side 264A compensates for the increasing circumferential area from wafer center 84 to wafer edge 34, and the top of wafer 32 (as shown in FIG. 6) can be coated evenly with liquid.

Shown in FIG. 7B is another alternate embodiment liquid dispenser 252A′ having slotted head outlets 294A′. In the illustrated embodiment, there are longer (and therefore larger) head outlets 294A′ near reservoir fill side 264A of liquid dispenser 252A′ than near tip 300A of liquid dispenser 252A′. More generally, the configuration of the array of head outlets 294A′ creates an increasing gradient of available dispensing area from tip 300A to reservoir fill side 264A of liquid dispenser 252A′.

Shown in FIG. 7C is another alternate embodiment liquid dispenser 252A″ having differently sized holes for head outlets 294A″. In the illustrated embodiment, there is a larger head outlet 294A″ near reservoir fill side 264A of liquid dispenser 252A″ than near tip 300A of liquid dispenser 252A″. More generally, the configuration of the array of head outlets 294A″ creates an increasing gradient of available dispensing area from tip 300A to reservoir fill side 264A of liquid dispenser 252A″.

The components and configuration of liquid dispensers 252A/252A′/252A″ as shown in FIGS. 7A-7C allow for the temperature of the liquid to be maintained at a substantially constant and known temperature, regardless of the incoming temperature of the liquid prior to entering liquid reservoir 258A. In addition, the configuration of dispensing plate 268A allows for dispensing that compensates for the changing characteristics of circumference and area of wafer 32 (as shown in FIG. 6) the farther away from wafer center 84 the dispensing occurs. More specifically, the array of head outlets 294A/294A′/294A″ has more flow area available the farther away from tip 300A than near tip 300A.

In FIG. 8, a top view of an alternate embodiment wafer cleaning system 250 is shown, including two liquid dispensers 252A-252B dispensing liquid onto wafer 32. Shown in FIG. 8 are wafer 32, chuck grippers 42A-42C, wafer rotation direction 82, wafer center 84, wafer edge 34, liquid dispensers 252A-252B, liquid reservoirs 258A-258B, reservoir fill sides 264A-264B, liquid puddles 274A-274B, liquid menisci 292A-292B, dispense point 308, dispense point 310, first wafer point 312, and second wafer point 314.

The individual parts and configuration of liquid dispensers 252A-252B are as previously explained with FIGS. 6 and 7A. However, in the illustrated embodiment, liquid dispenser 252B is positioned on the opposite side of wafer 32 from liquid dispenser 252A. Therefore, liquid dispensers 252A-252B are circumferentially spaced apart by an angle of one hundred eighty degrees center-to-center.

For explanatory purposes, liquid dispensers 252A-252B have dispense points 308-310, respectively. Dispense point 308 is located on liquid dispenser 252A near the outside end of liquid reservoir 258A near reservoir fill side 264A. Dispense point 310 is located on liquid dispenser 252B near the outside end of liquid reservoir 258B near reservoir fill side 264B. Dispense points 308 and 310 exist to show the respective outer ends of the central radial lines upon which liquid dispensers 252A-252B dispense. Similarly, wafer 32 has first wafer point 312 and second wafer point 314 in order to show where and/or when liquid dispensers 252A-252B have dispensed, respectively.

Liquid dispensers 252A-252B are shown in their respective dispensing positions with reservoir dispense sides 266A-266B adjacent to the wafer holding position of chuck 40 where wafer 32 is. As stated previously, wafer 32 is held by chuck grippers 42A-42C and rotated about wafer center 84 by chuck 40 (as shown in FIG. 6) in wafer rotation direction 82. Liquid dispensers 252A-252B dispense liquid onto wafer 32 while wafer 32 is rotating. In the illustrated embodiment, liquid dispensers 252A-252B have been dispensing the same liquid onto wafer 32 for a period of time. More specifically, liquid dispensers 252A-252B commenced dispensing substantially simultaneously when first wafer point 312 was under dispense point 308 and when second wafer point 314 was under dispense point 310.

At the point in time illustrated in FIG. 8, liquid puddles 274A-274B have been formed by liquid dispensers 252A-252B, respectively. As stated previously, liquid puddles 274A-274B have liquid menisci 292A-292B around their respective perimeters. However, once wafer 32 is rotated farther such that first wafer point 312 is under dispense point 310 and second wafer point 314 is under dispense point 308, liquid menisci 292A-292B will partially break down. More specifically, liquid menisci 292A-292B stretching from wafer center 84 outwards to wafer points 312-314, respectively, will merge. Such merging will combine liquid puddles 274A-274B into a single liquid puddle.

As stated previously, liquid dispensers 252A-252B can dispense the same liquid. Therefore, if the process being performed by wafer cleaning system 20 requires more than one liquid, each liquid dispenser 252A-252B can selectively receive liquid from two different sources containing two different liquids. Alternatively, there can be more than two liquid dispensers 252, with the additional liquid dispenser(s) 252 dispensing different liquids from liquid dispensers 252A-252B.

The components, configuration, and operation of liquid dispensers 252A-252B as shown in FIG. 8 allow for at least one liquid to be dispensed onto wafer 32 and form liquid puddles 274A-274B and/or mixed puddle 275 (as shown later with FIG. 9). Thereby, processing of wafer 32 can occur due to the interaction between the liquid and wafer 32. Because wafer 32 can be covered rapidly, the interaction between the liquid and wafer 32 begins across the entire surface of wafer 32 without significant delay. In other words, the lag between the time where some areas of wafer 32 have been covered and the time where wafer 32 is covered is insignificant.

Depicted in FIG. 8 is one embodiment of the present invention, to which there are alternatives. For example, liquid dispensers 252A-252B can be trapezoidally shaped like liquid dispenser 152 (as shown in FIG. 3).

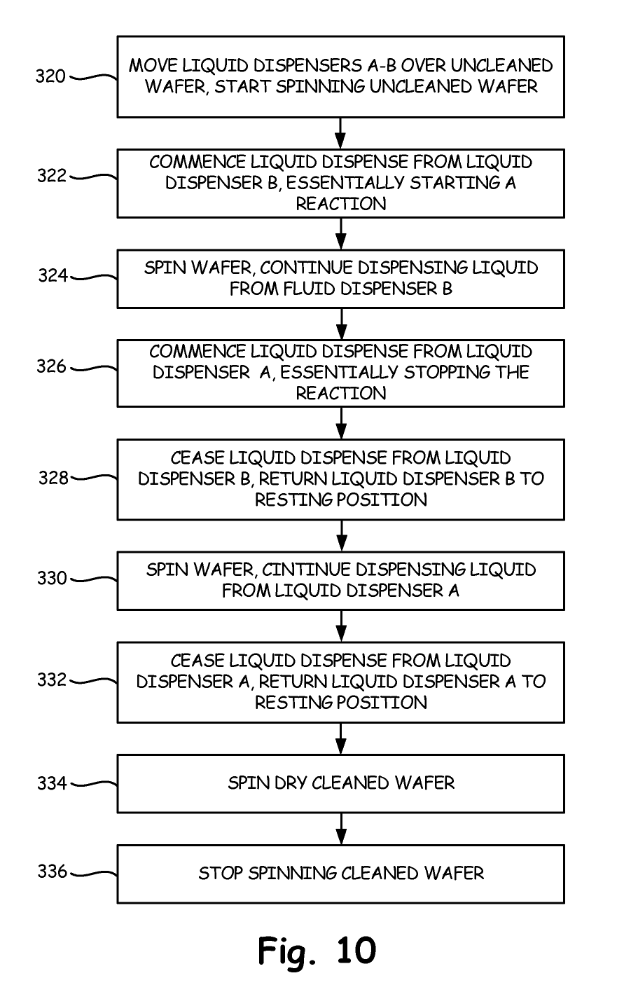

In FIG. 9, a top view of an alternate embodiment wafer cleaning system 250 is shown, including two liquid dispensers 252A-252B dispensing two liquids onto wafer 32. In FIG. 10, a flow diagram of a method for diluting one liquid on a wafer using another liquid is shown. Shown in FIGS. 9-10 are wafer 32, chuck grippers 42A-42C, wafer rotation direction 82, wafer center 84, wafer edge 34, liquid dispensers 252A-252B, liquid reservoirs 258A-258B, reservoir fill sides 264A-264B, liquid puddle 274B, mixed puddle 275, liquid menisci 292B-292C, dispense point 308, dispense point 310, first wafer point 312, and steps 320, 322, 324, 326, 328, 330, 332, 334, and 336.

The parts and configuration of liquid dispensers 252A-252B are as previously explained with FIGS. 6 and 7A. In the illustrated embodiment, liquid dispenser 252B is circumferentially spaced apart from liquid dispenser 252A by an angle of ninety degrees center-to-center. As with FIG. 8, liquid dispensers 252A-252B have dispense points 308 and 310, respectively. Dispense point 308 is located on liquid dispenser 252A near the outside end of liquid reservoir 258A near reservoir fill side 264A. Dispense point 310 is located on liquid dispenser 252B near the outside end of liquid reservoir 258B near reservoir fill side 264B. Dispense points 308 and 310 exist to show the respective outer ends of the central radial lines upon which liquid dispensers 252A-252B dispense. Similarly, wafer 32 has first wafer point 312 in order to show where and/or when liquid dispensers 252A-252B have dispensed, respectively.

Liquid dispensers 252A-252B are shown in their respective dispensing positions with reservoir dispense sides 266A-266B (as shown in FIGS. 7A-7C) adjacent to the wafer holding position of chuck 40 where wafer 32 is. As stated previously, wafer 32 is held by chuck grippers 42A-42C and rotated about wafer center 84 by chuck 40 (as shown in FIG. 6) in wafer rotation direction 82. Liquid dispensers 252A-252B dispense liquid onto wafer 32 while wafer 32 is rotating. In the illustrated embodiment, liquid dispensers 252A-252B have been dispensing liquid onto wafer 32 different periods of time, respectively. More specifically, liquid dispenser 252B commenced dispensing when first wafer point 312 was under dispense point 310. Subsequently, liquid dispenser 252A commenced dispensing when first wafer point 312 was under dispense point 308.

At the point in time illustrated in FIG. 9, liquid puddle 274B has been formed by liquid dispenser 252B, and mixed puddle 275 has been formed by both liquid dispensers 252A-252B. Liquid puddle 274B has liquid meniscus 292B along wafer edge 34 and along a radial line stretching from wafer center 84 to wafer edge 34 under liquid reservoir 258B. Mixed puddle 275 has liquid meniscus 292C along wafer edge 34 and along a radial line stretching from wafer center 84 outwards to wafer edge 34, ending at first wafer point 312. Prior to the commencement of dispensing by liquid dispenser 252A, only the liquid from liquid dispenser 252B was interacting with wafer 32. However, after liquid dispenser 252A commenced dispensing, liquids from both liquid dispensers 252A-252B have interacted with wafer 32 and with each other.

In the illustrated embodiment, the liquid from liquid dispenser 252B is a cleaning chemical and the liquid from liquid dispenser 252A is ultra pure water (UPW). The cleaning chemical can be, but is not limited to, hydrochloric acid, ammonium hydroxide, hydrogen peroxide, hydrofluoric acid, ammonium fluoride, or any suitable mixture of cleaning chemicals.

While UPW does not react with wafer 32, UPW can dilute the cleaning chemical. Therefore, the UPW essentially stops the interaction between wafer 32 and the cleaning chemical. In addition, liquid dispenser 252A can dispense the first liquid at a rate that puts more liquid on wafer 32 than liquid meniscus 292C can retain. Thereby, liquid meniscus 292C can break along wafer edge 34 allowing the liquid mixture to be rinsed off of wafer 32.

Because of the configuration and operation of liquid dispensers 252A-252B as illustrated in FIG. 9, the method for cleaning wafer 32 in wafer cleaning system 250 can be different. In FIG. 10, an alternative embodiment method for cleaning wafer 32 is shown. At step 320, liquid dispensers 252A-252B are raised up from their respective resting positions, rotated over uncleaned wafer 32, and dropped down slightly near the surface of uncleaned wafer 32. Also at step 320, wafer spin motor (not shown) connected to chuck 40 (shown in FIG. 6) begins rotating uncleaned wafer 32. At step 322, liquid dispenser 252B commences dispensing of a second liquid on to uncleaned wafer 32 when first wafer point 312 reaches dispense point 310. This essentially locally starts the reaction between the chemicals and wafer 32. At step 324, liquid dispenser 252B dispenses the second liquid while uncleaned wafer 32 is spinning. At step 326, liquid dispenser 252A commences dispensing of the first liquid into liquid puddle 274B on uncleaned wafer 32 when first wafer point 312 reaches dispense point 308. This dilutes the second liquid and/or rinses the liquid mixture over wafer edge 34, off of wafer 32, essentially locally stopping the reaction between the chemicals and wafer 32. Also at step 326, liquid dispenser 252B continues to dispense the second liquid and wafer 32 continues to spin. At step 328, liquid dispenser 252B ceases dispensing when first wafer point 312 reaches dispense point 310. Additionally, liquid dispenser 252B is returned to its resting position (similar to resting position 69 in FIG. 1) at step 328. At step 330, liquid dispenser 252A dispenses the first liquid while wafer 32 is spinning. This essentially globally stops the reaction between the chemicals and wafer 32. At step 332, liquid dispenser 252A ceases dispensing when first wafer point 312 reaches dispense point 308. Additionally, liquid dispenser 252A is returned to its resting position (similar to resting position 68 in FIG. 1) at step 332. At step 334, the rate of rotation of the wafer spin motor is adjusted to spin dry newly cleaned wafer 32. In the present embodiment, the rotational rate is substantially increased at step 334. At step 336, the wafer spin motor (not shown) ceases rotation of cleaned wafer 32.

The components, configuration, and operation of liquid dispensers 252A-252B as shown in FIGS. 9-10 allow for wafer 32 to be cleaned. More specifically, one liquid can be dispensed onto and react with wafer 32, and then that liquid can be diluted and/or rinsed off with another liquid in rapid succession without having wafer 32 rotating quickly. The amount of time that the second liquid has to react with wafer 32 prior to being diluted is a function of the speed of rotation of wafer 32 and the circumferential spacing between liquid dispensers 252A-252B. In addition, the second liquid can react and the first liquid can dilute substantially evenly over the top of wafer 32 due to liquid dispensers 252A-252B dispensing over two central radial lines, respectively.

Depicted in FIGS. 9-10 is one embodiment of the present invention, to which there are alternatives. For example, liquid dispensers 252A-252B can be circumferentially spaced more or less than ninety degrees center-to-center (for example, one hundred eighty degrees center-to-center, as shown in FIG. 8). For another example, wafer 32 can make a more that one full rotation at step 324, after liquid dispenser 252B commences dispensing at step 322. In such an embodiment, liquid dispenser 252B commences dispensing at step 326 when first wafer point 312 reaches dispense point 310 for the second time. For a further example, wafer 32 can make a more that one full rotation at step 330, after liquid dispenser 252B ceased dispensing at step 328. In such an embodiment, liquid dispenser 252A ceases dispensing at step 332 when first wafer point 312 reaches dispense point 308 for the second time.

It should be recognized that the present invention provides numerous benefits and advantages. For example, wafer 32 can be covered with liquid quickly. This allows for a lower process time and increases uniformity because there is little lag time between when the first area of wafer 32 starts reacting with the liquid and when the last area of wafer 32 starts reacting.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A wafer cleaning method comprising:
dispensing liquid chemicals onto a wafer at a first flow rate to essentially start a chemical reaction between the chemicals and the wafer;
dispensing liquid chemicals onto the wafer at a second flow rate that is substantially lower than the first flow rate;
dispensing water onto the wafer at a third flow rate to essentially stop the chemical reaction between the chemicals and the wafer; and
dispensing water onto the wafer at a fourth flow rate that is substantially lower than the third flow rate.

2. The method of claim 1, wherein dispensing liquid chemicals onto the wafer covers the wafer with chemicals in less than four seconds.

3. The method of claim 1, wherein dispensing liquid chemicals onto the wafer covers the wafer with chemicals in less than two seconds.

4. The method of claim 1, wherein dispensing liquid chemicals onto the wafer covers the wafer with chemicals in less than one second.

5. The method of claim 1, wherein dispensing liquid water onto the wafer covers the wafer with water in less than four seconds.

6. The method of claim 1, wherein dispensing liquid water onto the wafer covers the wafer with water in less than two seconds.

7. The method of claim 1, wherein dispensing liquid water onto the wafer covers the wafer with water in less than one second.

8. The method of claim 1, wherein the first flow rate is at least 15 cubic centimeters per second.

9. The method of claim 1, wherein the first flow rate is at least 30 cubic centimeters per second.

10. The method of claim 1, wherein the first flow rate is at least 60 cubic centimeters per second.

11. The method of claim 1, wherein the second flow rate is at most 20 cubic centimeters per second.

12. The method of claim 1, wherein the second flow rate is at most 10 cubic centimeters per second.

13. The method of claim 1, wherein the third flow rate is at least 15 cubic centimeters per second.

14. The method of claim 1, wherein the third flow rate is at least 30 cubic centimeters per second.

15. The method of claim 1, wherein the third flow rate is at least 60 cubic centimeters per second.

16. The method of claim 1, wherein the fourth flow rate is at most 20 cubic centimeters per second.

17. The method of claim 1, wherein the fourth flow rate is at most 10 cubic centimeters per second.

18. The method of claim 1, and further comprising:
spinning the wafer.

19. The method of claim 1, and further comprising:
ceasing dispensing water at the fourth flow rate; and
spin drying the wafer.

20. A system for dispensing a liquid onto a wafer comprising:
a chuck for holding the wafer, the chuck having a center axis about which the chuck rotates and a wafer holding position where the wafer is held; and
a first liquid dispenser for receiving and dispensing liquid, the first liquid dispenser being positionable over the chuck and comprising:
a first supply tube for having a first inlet at a first end of the supply tube and a first outlet at a second end of the supply tube; and
a first valve attached to the first supply tube between the first inlet and the first outlet for controlling the dispensing of the liquid from the first liquid dispenser; and
a second liquid dispenser for receiving and dispensing liquid, the second liquid dispenser being positionable over the chuck and comprising:
a second supply tube for having a second inlet at a first end of the supply tube and a second outlet at a second end of the supply tube; and
a second valve attached to the second supply tube between the second inlet and the second outlet for controlling the dispensing of the liquid from the second liquid dispenser;
wherein the first liquid dispenser dispenses liquid at a substantially higher rate than the second liquid dispenser.

21. The system of claim 20, wherein an inner diameter of the first supply tube is substantially larger than an inner diameter of the second supply tube.

22. The system of claim 20, wherein an inner diameter of the first supply tube is at least 1.59 centimeters.

23. The system of claim 20, wherein an inner diameter of the second supply tube is at most 0.635 centimeters.

24. The system of claim 20, wherein the first liquid dispenser dispenses at least 15 cubic centimeters of liquid per second.

25. The system of claim 20, wherein the first liquid dispenser dispenses at least 30 cubic centimeters of liquid per second.

26. The system of claim 20, wherein the first liquid dispenser dispenses at least 60 cubic centimeters of liquid per second.

27. The system of claim 20, wherein the second liquid dispenser dispenses at most 20 cubic centimeters of liquid per second.

28. The system of claim 20, wherein the second liquid dispenser dispenses at most 10 cubic centimeters of liquid per second.
